(19) United States
(12) Patent Application Publication
(10) Pub. No.: US 2025/0203963 A1
(43) Pub. Date: Jun. 19, 2025

(54) STACKED FET WITH DOPED GATE DIELECTRIC

(71) Applicant: INTERNATIONAL BUSINESS MACHINES CORPORATION, ARMONK, NY (US)

(72) Inventors: Ruqiang Bao, Niskayuna, NY (US); Jingyun Zhang, Albany, NY (US); Oleg Gluschenkov, Tannersville, NY (US)

(21) Appl. No.: 18/389,703

(22) Filed: Dec. 19, 2023

(51) Int. Cl. H01L 29/06; H01L 21/8238; H01L 25/07; H01L 27/092; H01L 29/423; H01L 29/66; H01L 29/775; H01L 29/786

(52) U.S. Cl. CPC H10D 62/115; H01L 25/074; H10D 30/014; H10D 30/43; H10D 30/6735; H10D 30/6757; H10D 62/121; H10D 84/0167; H10D 84/0188; H10D 84/038; H10D 84/85

(57) ABSTRACT

A semiconductor device includes a top transistor, a bottom transistor, an isolation box between the top transistor and the bottom transistor, a first gate dielectric, and a second gate dielectric. First portions of the first gate dielectric cover a top surface and top-half of sidewalls of the isolation box, and first portions of the second gate dielectric cover a bottom surface and bottom-half of the sidewalls of the isolation box.

### BACKGROUND

### Technical Field

The present disclosure generally relates to transistors, and more particularly, to transistors with doped gate dielectric structure and methods of creation thereof.

### Description of the Related Art

As the semiconductor device layers are sequenced vertically in a stacked transistor, the integrity of the lower transistor's gate stack must be maintained through all upper transistor fabrication steps where the structure experiences prolonged heat cycles and processing exposures. Therefore, the quality and reliability of that buried oxide layer underneath the bottom conductive gate electrode helps determine the overall stacked transistor performance and lifetime. Any degradation mechanisms such as trapped charges, dielectric breakdowns, or reaction layers formed in the insulator during processing would alter the bottom transistor's turn-on voltage.

### SUMMARY

According to an embodiment, a semiconductor device includes a top transistor, a bottom transistor, an isolation box between the top transistor and the bottom transistor, a first gate dielectric, and a second gate dielectric. First portions of the first gate dielectric cover a top surface and top-half of sidewalls of the isolation box, and first portions of the second gate dielectric cover a bottom surface and bottom-half of the sidewalls of the isolation box.

In some embodiments, the top transistor is stacked over the bottom transistor, and wherein the top transistor and the bottom transistor are nanosheet field-effect transistors (FETs).

In some embodiments, second portions of the first gate dielectric encapsulate a first plurality of nanosheets in the top transistor, and second portions of the second gate dielectric encapsulate a second plurality of nanosheets in the bottom transistor.

In some embodiments, the first portions of the first gate dielectric and the first portions of the second gate dielectric form a continuous layer encapsulating the isolation box.

In seem embodiments, the first gate dielectric is made of a first high-k dielectric material, and the second gate dielectric is made of a second high-k dielectric material.

In some embodiments, the first high-k material and the second high-k materials are a same material.

In some embodiments, the first high-k material and the second high-k materials are different materials.

In some embodiments, the first gate dielectric is doped with a metal, and the second gate dielectric is an undoped material.

In some embodiments, the semiconductor device includes an n-type work function material in the bottom transistor, and a p-type work function material in the top transistor. In some embodiments, the n-type work function material includes Aluminum.

According to an embodiment, a method of fabricating a semiconductor includes forming a top transistor, forming a bottom transistor, forming an isolation box between the top transistor and the bottom transistor, covering a top surface and top-half of sidewalls of the isolation box by a first gate dielectric, and covering a bottom surface and bottom-half of sidewalls of the isolation box by a second gate dielectric.

In some embodiments, the method includes stacking the top transistor over the bottom transistor. The top transistor and the bottom transistor are nanosheet field-effect transistors (FETs).

In some embodiments, the method includes covering a first plurality of nanosheets in the top transistor by the first gate dielectric, and covering a second plurality of nanosheets in the bottom transistor by the second gate dielectric.

In some embodiments, the method includes encapsulating the isolation box by the first gate dielectric and the second gate dielectric by connecting the first gate dielectric and the second gate dielectric.

In some embodiments, the method includes doping the first gate dielectric with a dopant.

In some embodiments, the dopant is a metal dopant.

In some embodiments, the method includes forming an n-type work function metal in the bottom transistor, and forming a p-type work function metal in the top transistor.

According to an embodiment, a semiconductor device includes a top transistor, a bottom transistor, a first gate dielectric, and a second gate dielectric. Portions of the first gate dielectric encapsulate a first plurality of nanosheets in the top transistor, and portions of the second gate dielectric encapsulate a second plurality of nanosheets in the bottom transistor.

In some embodiments, the first gate dielectric is made of a first high-k dielectric material doped with a metal, and the second gate dielectric is made of a second high-k dielectric material.

In some embodiments, the semiconductor device includes an n-type work function metal in the bottom transistor, and a p-type work function material in the top transistor.

These and other features will become apparent from the following detailed description of illustrative embodiments thereof, which is to be read in connection with the accompanying drawings.

### BRIEF DESCRIPTION OF THE DRAWINGS

The drawings are of illustrative embodiments. They do not illustrate all embodiments. Other embodiments may be used in addition or instead. Details that may be apparent or unnecessary may be omitted to save space or for more effective illustration. Some embodiments may be practiced with additional components or steps and/or without all the components or steps that are illustrated. When the same numeral appears in different drawings, it refers to the same or like components or steps.

FIGS. 1A-1B illustrate a semiconductor device, in accordance with some embodiments.

FIG. 1C depicts the side-view sections from which the semiconductor device is illustrated.

FIGS. 2A-2B illustrate a semiconductor device after formation of the organic planarization layer, in accordance with some embodiments.

FIG. 2C illustrates a nanosheet of the semiconductor device after the formation of the organic planarization layer, in accordance with some embodiments.

FIGS. 3A-3B illustrate a semiconductor device after the organic planarization layer reflow, in accordance with some embodiments.

FIG. 3C illustrates a nanosheet of the semiconductor device after the organic planarization layer reflow, in accordance with some embodiments.

FIGS. 4A-4B illustrate a semiconductor device after the organic planarization layer removal, in accordance with some embodiments.

FIG. 4C illustrates a nanosheet of the semiconductor device after the organic planarization layer removal, in accordance with some embodiments.

FIGS. 5A-5B illustrate a semiconductor device after formation of an n-dipole, in accordance with some embodiments.

FIG. 5C illustrates a nanosheet of the semiconductor device after formation of an n-dipole, in accordance with some embodiments.

FIGS. 6A-6B illustrate a semiconductor device after formation of sacrificial TiN, in accordance with some embodiments.

FIG. 6C illustrates a nanosheet of the semiconductor device after formation of sacrificial TiN, in accordance with some embodiments.

FIGS. 7A-7B illustrate a semiconductor device after removal of the sacrificial TiN, in accordance with some embodiments.

FIG. 7C illustrates a nanosheet of the semiconductor device after removal of the sacrificial TiN, in accordance with some embodiments.

FIGS. 8A-8B illustrate a semiconductor device after the gate patterning, in accordance with some embodiments.

FIG. 8C illustrates a nanosheet of the semiconductor device after the gate patterning, in accordance with some embodiments.

FIGS. 9A-9B illustrate a semiconductor device after the first gate dielectric doping, in accordance with some embodiments.

FIG. 9C illustrates a nanosheet of the semiconductor device after the first gate dielectric doping, in accordance with some embodiments.

FIGS. 10A-10B illustrate a semiconductor device after formation of the work function metals, in accordance with some embodiments.

FIGS. 11A-11B illustrate a semiconductor device after removing portions of the top work function metal, in accordance with some embodiments.

FIGS. 12A-12B illustrate a semiconductor device after contact formation, in accordance with some embodiments.

FIG. 13 illustrates a block diagram of a method for forming the semiconductor device, in accordance with some embodiments.

### DETAILED DESCRIPTION

### Overview

In the following detailed description, numerous specific details are set forth by way of examples to provide a thorough understanding of the relevant teachings. However, it should be apparent that the present teachings may be practiced without such details. In other instances, well-known methods, procedures, components, and/or circuitry have been described at a relatively high-level, without detail, to avoid unnecessarily obscuring aspects of the present teachings.

In one aspect, spatially related terminology such as “front,” “back,” “top,” “bottom,” “beneath,” “below,” “lower,” above,” “upper,” “side,” “left,” “right,” and the like, is used with reference to the orientation of the Figures being described. Since components of embodiments of the disclosure can be positioned in a number of different orientations, the directional terminology is used for purposes of illustration and is in no way limiting. Thus, it will be understood that the spatially relative terminology is intended to encompass different orientations of the device in use or operation in addition to the orientation depicted in the figures. For example, if the device in the figures is turned over, elements described as “below” or “beneath” other elements or features would then be oriented “above” the other elements or features. Thus, for example, the term “below” can encompass both an orientation that is above, as well as, below. The device may be otherwise oriented (rotated 90 degrees or viewed or referenced at other orientations) and the spatially relative descriptors used herein should be interpreted accordingly.

As used herein, the terms “lateral” and “horizontal” describe an orientation parallel to a first surface of a chip.

As used herein, the term “vertical” describes an orientation that is arranged perpendicular to the first surface of a chip, chip carrier, or semiconductor body.

As used herein, the terms “coupled” and/or “electrically coupled” are not meant to mean that the elements must be directly coupled together-intervening elements may be provided between the “coupled” or “electrically coupled” elements. In contrast, if an element is referred to as being “directly connected” or “directly coupled” to another element, there are no intervening elements present. The term “electrically connected” refers to a low-ohmic electric connection between the elements electrically connected together.

Although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of example embodiments. As used herein, the term “and/or” includes any and all combinations of one or more of the associated listed items.

Example embodiments are described herein with reference to cross-sectional illustrations that are schematic illustrations of idealized or simplified embodiments (and intermediate structures). As such, variations from the shapes of the illustrations as a result, for example, of manufacturing techniques and/or tolerances, may be expected. Thus, the regions illustrated in the figures are schematic in nature and their shapes do not necessarily illustrate the actual shape of a region of a device and do not limit the scope.

It is to be understood that other embodiments may be used and structural or logical changes may be made without departing from the spirit and scope defined by the claims. The description of the embodiments is not limiting. In particular, elements of the embodiments described hereinafter may be combined with elements of different embodiments.

As used herein, certain terms are used indicating what may be considered an idealized behavior, such as, for example, “lossless,” “superconductor,” or “superconducting,” which are intended to cover functionality that may not be exactly ideal but is within acceptable margins for a given application. For example, a certain level of loss or tolerance may be acceptable such that the resulting materials and structures may still be referred to by these “idealized” terms.

The concepts herein relate to nanosheet field-effect transistor (FET), which are fundamental electronic devices that have revolutionized the field of electronics and how various elements of the transistors are electrically connected. In a monolithic 3D stacked transistor architecture with two-tiers of devices sequentially fabricated in a vertical stack, tuning the individual work functions and thresholds is inherently asymmetric due to process integration constraints. Achieving the desired work function dipole and threshold voltage (Vt) for the lower bottom-tier transistor is relatively more straightforward. This first transistor level can leverage well established blocking layers embedded locally in the gate metal stack to tune its work function during the initial fabrication step.

However, independently defining a second different work function for solely the upper top-tier transistor in the 3D vertical stack with a tailored blocking layer is substantially more difficult. This is because the top transistor gate assembly must be fabricated after the bottom one, constraining its process conditions to maintain the lower transistor integrity. Current manufacturing schemes cannot selectively remove work function/threshold influencing materials only from the upper gate metal layers during the second transistor fabrication step as needed. So far, no known solution for selective removal to enable differential work function exclusive to only the top device has been achieved using standard CMOS-compatible processing.

Being able to reliably and repeatably engineer a tailored work function specifically adapted for the upper stacked transistor can enable multiple Vt devices in a monolithic 3D layout. This would maximize density and flexibility when designing complementary high performance logic circuits. However, there is still room for significant innovation in selective disposable gate stack materials, etch techniques, and integration schemes before this becomes technically and economically feasible using manufacturing-worthy approaches.

To tackle the above-mentioned and other considerations, disclosed is a semiconductor device with doped gate dielectric. In the disclosed semiconductor, the lower bottom-tier transistor's gate metal stack is first fabricated with an embedded blocking layer to define its work function and threshold voltage (Vt). Such a blocking region in the bottom device gate assembly also serves as the foundational first block layer to subsequently allow tuning of the work function exclusively for the upper top-tier transistor separately.

In an aspect, after forming the bottom transistor and interconnect, the gate metals are deposited for the top-tier transistor. A tailored work function dipole layer sequence is added, such as 3-5 cycles of a metal n-type dipole layer, followed by deposition of a sacrificial cap layer on top which also covers the lower transistor's gate. A selective etch process completely strips the cap material from both the bottom and top-tier device gate regions, leaving only the n-type dipole layers intact just on the top transistor's gate stack.

The disclosed process sequence thereby enables independent work function/Vt control for the upper stacked transistor using the bottom transistor's blocking and sacrificial cap approach to selectively retain only a tuned dipole layer for the top device gate during fabrication. The result is a semiconductor device with dual work function definition on a monolithic vertically stacked pair of transistors for optimized threshold control.

Accordingly, the teachings herein provide methods and systems of semiconductor device formation with doped gate dielectric. The techniques described herein may be implemented in a number of ways. Example implementations are provided below with reference to the following figures.

### Example Semiconductor Device With Doped Gate Dielectric Structure

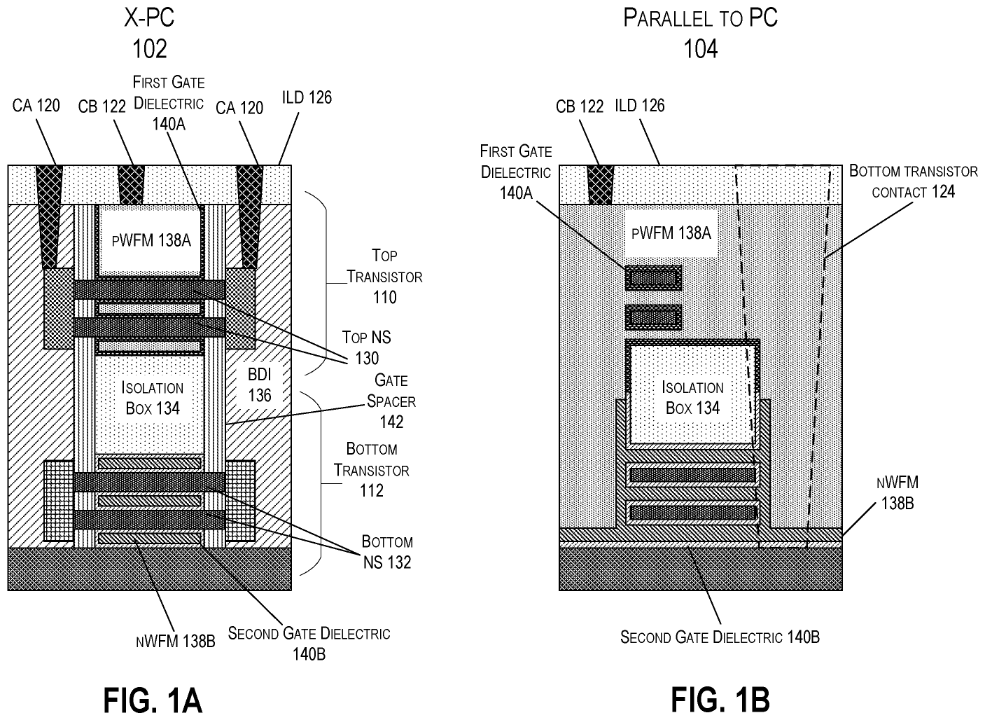

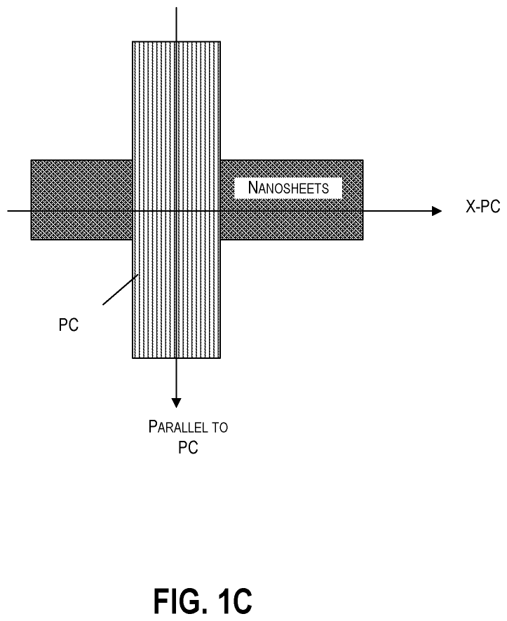

Reference now is made to FIGS. 1A-1B, which are simplified cross-section views of a semiconductor device across gates 102, as shown in FIG. 1A, and parallel to the gates 104, as shown in FIG. 1B, consistent with an illustrative embodiment. The disclosed semiconductor device can include a top transistor 110 and a bottom transistor 112. The top transistor 110 can be stacked over the bottom transistor 112. In various embodiments, the semiconductor device includes a stacked FET that leverages the vertical dimension of the semiconductor device to increase the number of active devices within a given area. This way, instead of relying solely on lateral scaling, where semiconductor devices are shrunk in size on the semiconductor substrate, stacking FETs vertically can enable the incorporation of multiple layers of semiconductor devices. This arrangement enables more complex circuitry and advanced functionality.

In several embodiments, the stacked FET structure within the semiconductor device can enable higher integration densities by utilizing the vertical dimension of the semiconductor device. In such embodiments, instead of relying solely on lateral scaling, which has its limits, stacking FETs on the semiconductor device allows for increased transistor count within a given chip area. This increased transistor count enables the integration of more complex circuits, larger memory arrays, and other functional blocks, enhancing the capabilities of the semiconductor device.

The top transistor includes one or more source/drain contacts, CA, 120A, a gate contact, CB, 122, a first gate dielectric 140A, a top plurality of nanosheets, top NS, 130, and a work function metal, p-type work function metal (pWFM), 138A. The bottom transistor 112 includes a bottom transistor contact 124, a second gate dielectric 140B, a bottom plurality of nanosheets, bottom NS, 132, and a work function metal, n-type work function metal (nWFM), 138B. The semiconductor device can further include an interlayer dielectric, ILD, 126 over the top transistor 110, a dielectric layer, BDI, 136, a gate spacer 142, and an isolation box 134 between the top transistor 110 and the bottom transistor 112. It should be noted that, the semiconductor device can include other components such as source/drain regions, wirings for the power delivery network and other components, which for the sake of simplicity, are not shown.

CA 120 is a doped semiconductor region situated at opposite ends of the conducting channel. CA 120 forms low resistance metal/semiconductor junctions that allow current to flow into and out of the top transistor channel. In some embodiments, silicide materials are layered atop the source/drain region of the top transistor 110 to provide metal contact with low resistance for extracting signal current to the next circuit stage.

CB 122 can be a gate electrode which applies electric field across the gate dielectric onto the semiconductor channel underneath to dynamically control conductivity and switch channel current on/off. In some embodiments, CB 122 is made from polysilicon or a layered metallic stack and handles high frequencies. In some embodiments, CB 122 can be isolated from the channel except through the gate dielectric.

The first gate dielectric 140A can be an insulating region separating the gate electrode from the top transistor channel, and can be made of hafnium-based oxides with nanometer scale thickness engineered to minimize leakage. The first gate dielectric 140A can transmit lateral electric field from the gate for modulation while blocking direct conduction.

Top NS 130 can be alternating, vertically oriented sheets, which can drive current in a small footprint area. In some embodiments, top NS 130 includes silicon nanowires. In other words, top NS 130 include three-dimensional structures in the gate channel, which are extended from a source region towards a drain region.

The pWFM 138A can determine the threshold voltage of the top transistor 110. The threshold voltage is the gate voltage at which the top transistor 110 starts to conduct. A difference in work function between the gate material and the semiconductor material, i.e., difference between pWFM 138A and nWFM 138B, creates an energy barrier which influences the amount of voltage required to induce a conducting channel in the semiconductor device.

The bottom transistor contact 124, is a doped semiconductor regions situated at opposite ends of the conducting channel. The bottom transistor contact 124 forms low resistance metal/semiconductor junctions that allow current to flow into and out of the top transistor channel. In some embodiments, silicide materials are layered atop the source/drain region of the bottom transistor 112 to provide metal contact with low resistance for extracting signal current to the next circuit stage.

The second gate dielectric 140B, can be an insulating region separating the gate electrode from the bottom transistor channel, and can be made of hafnium-based oxides with nanometer scale thickness engineered to minimize leakage. The second gate dielectric 140B can transmit lateral electric field from the gate for modulation while blocking direct conduction.

The bottom NS 132 can be alternating, vertically oriented sheets, which can drive current in a small footprint area. In some embodiments, bottom NS 132 includes silicon nanowires. In other words, bottom NS 132 includes three-dimensional structures in the gate channel, which are extended from a source region towards a drain region.

The nWFM 138B can determine the threshold voltage of the bottom transistor 112. The threshold voltage is the gate voltage at which the bottom transistor 112 starts to conduct. The nWFM 138B can include Al or Ti.

The ILD, 126 can act as an electrical insulator, preventing unwanted electrical crosstalk and leakage between the layers. In some embodiments, ILD 126 provides mechanical support and structural integrity to the multi-layered architecture of the semiconductor device, and ensures that the layers above and below the ILD 126 remain intact and correctly aligned.

The BDI 136 can act as a gate insulator, separating the gate electrode from the semiconductor channel below. Such a separation can help in controlling the semiconductor device's operation, in that it allows the gate voltage to modulate the charge carrier concentration in the channel without direct current flow into the gate.

The gate spacer 142 is an insulating material layer that surrounds and isolates the gate electrode of the semiconductor device. The gate spacer 142 electrically isolates the gate channel from a source/drain region to prevent unwanted electrical leakage. In some embodiments, the gate spacer 142 can help define the length of the gate channel beneath the gate electrode. In some embodiments, the gate spacer is made of silicon dioxide (SiO2), silicon nitride (Si3N4), or a high-k dielectric.

The isolation box 134 which is located between the top transistor 110 and the bottom transistor 112 in the stacked FET arrangement of the semiconductor device ensures that the top transistor 110 and the bottom transistor 112 operate independently of each other. The isolation box 134 can prevent electrical interference and thermal crosstalk between the stacked transistors, and ensure that the operation of one transistor does not inadvertently impact the behavior of the adjacent transistor, which is particularly important in high-density circuit designs where heat dissipation and electrical isolation are major concerns.

In some embodiments, the first portions of the first gate dielectric 140A cover a top surface and top-half of sidewalls of the isolation box 134. Similarly, the first portions of the second gate dielectric 140B cover a bottom surface and bottom-half of the sidewalls of the isolation box 134. The first portions of the first gate dielectric and the first portion of the second gate dialectic can connect to each other to form a continuous layer around the isolation box 134. That is, the isolation box 134 is encapsulated by the first portions of the first gate dielectric 140A and the first portions of the second gate dielectric 140B.

In some embodiments, second portions of the first gate dielectric 140A encapsulate the top NS 130 in the top transistor 110. Similarly, the second portions of the second gate dielectric 140B encapsulate the bottom NS 132 in the bottom transistor 112.

In some embodiments, the first gate dielectric 140A is made of a high-k dielectric material. The second gate dielectric 140B can be made of a high-k dielectric material. While the first gate dielectric 140A and the second gate dielectric 140B can be made of the same high-k dielectric material, in some embodiments, the first gate dielectric 140A and the second gate dielectric 140B are made of different high-k dielectric materials. In some embodiments, the first gate dielectric 140A is doped with a metal, i.e., metal dopant. The metal dopant can be Ti, Al, La, Y, or Mg. The second gate dielectric 140B is an undoped high-k dielectric material.

### Example Fabrication Acts Of Semiconductor Device With Doped Gate Dielectric

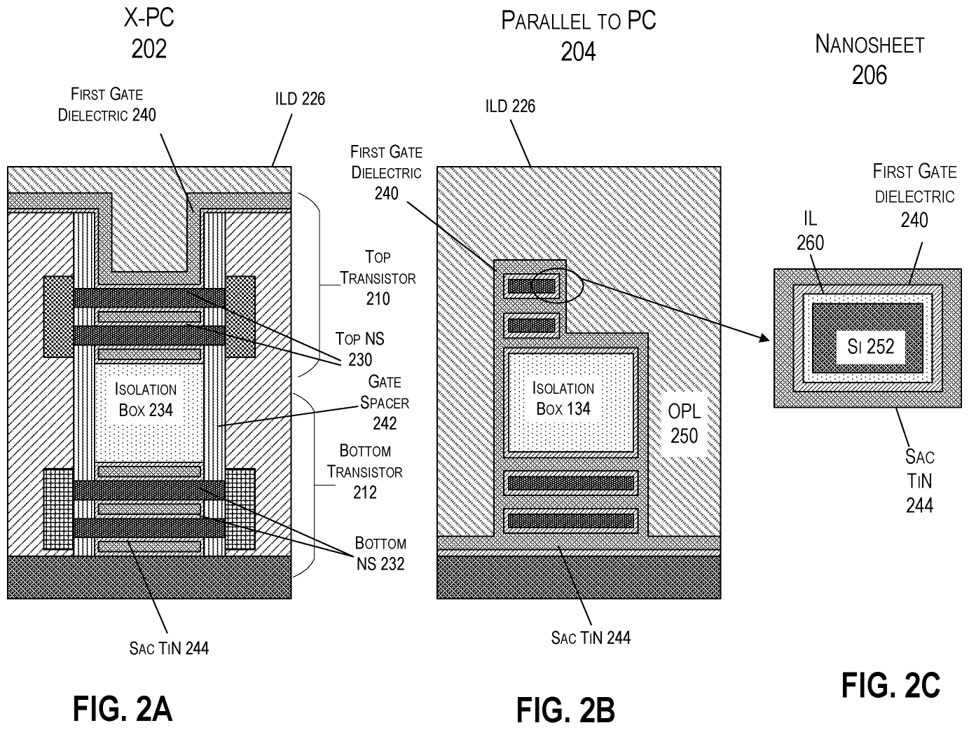

With the foregoing description of an example semiconductor device, it may be helpful to discuss an example process of manufacturing the same. To that end, FIGS. 2-14 illustrate various acts in the manufacture of a semiconductor device, consistent with illustrative embodiments. Figures denoted by A and B illustrate an act of fabrication of the semiconductor device from a different point of view. Reference now is made to FIGS. 2A-2B, which are simplified cross-section views of a semiconductor device across gates 202 and parallel to gates 204, after formation of the nanosheets, consistent with an illustrative embodiment. The disclosed semiconductor device can include a top transistor 210 stacked over a bottom transistor 212. The top transistor 210 includes a first gate dielectric 240, and a top plurality of nanosheets, top NS, 230. The bottom transistor 212 includes a bottom plurality of nanosheets, bottom NS, 232. The semiconductor device can further include an interlayer dielectric, ILD, 226 over the top transistor 210, a gate spacer 242, an isolation box 234 between the top transistor 210 and the bottom transistor 212, and a sacrificial layer, sac TIN, 244.

In some embodiments, an organic planarization layer, OPL, 250 is formed over the semiconductor device. The OPL 250 can include a photo-sensitive organic polymer having a light-sensitive material that, when exposed to electromagnetic (EM) radiation, is chemically altered and thus configured to be removed using a developing solvent. For example, the photo-sensitive organic polymer can be polyacrylate resin, epoxy resin, phenol resin, polyamide resin, polyimide resin, unsaturated polyester resin, polyphenylenether resin, polyphenylenesulfide resin, or benzocyclobutene (BCB). In some embodiments, the OPL 250 can include any organic polymer and a photoactive compound having a molecular structure that can attach to the molecular structure of the organic polymer. The OPL 250 material can be selected to be compatible with an overlying antireflective coating (not shown) and/or an overlying photoresist (not shown). The OPL 250 can be applied using spin coating technology, although other techniques are within the contemplated scope of the present disclosure.

FIG. 2C illustrates an augmented top view of a nanosheet 206 of the top transistor 210, in accordance with some embodiments. As depicted, the nanosheet includes a silicon layer, Si, 252 in the middle of the nanosheet surrounded by a dielectric layer, IL 260. The first gate dielectric 240 is formed over the IL 260 and the sac TiN 244 is formed over the first gate dielectric 240.

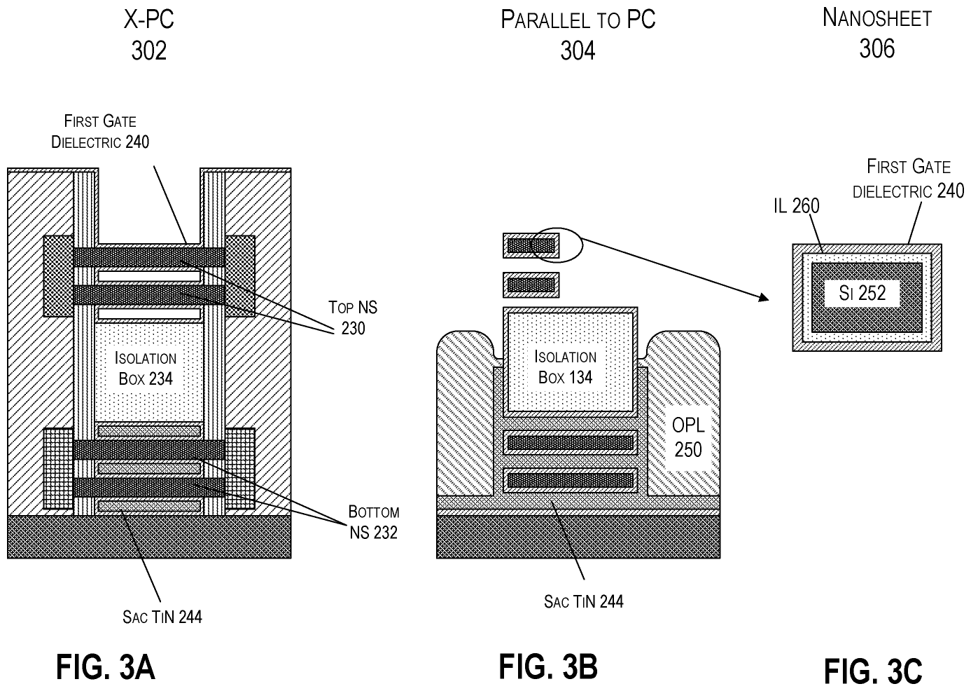

FIGS. 3A-3B illustrate a semiconductor device after the OPL reflow, in accordance with some embodiments. The semiconductor device is shown across gates 302 and parallel to gates 304. The OPL 350 can be baked at a low temperature, e.g., about 200-250 0C. Portions of OPL 350 are removed via a reactive ion etching (RIE), which stops at the similar level as top surface of isolation box 234. Generally, RIE is a dry etching process used in semiconductor device fabrication to remove materials from the surface of a substrate selectively. RIE can involve the use of reactive ions and plasma to react with and remove specific materials chemically. For example, the RIE process begins by placing the semiconductor device inside a vacuum chamber. The chamber is then evacuated to create a low-pressure environment. Reactive gases, which can include a combination of a chemically reactive gas and an inert gas, are introduced into the chamber. The chemically reactive gas, such as fluorine-based gases (e.g., CF4, SF6) or chlorine-based gases (e.g., Cl2), can react with the material to be etched, i.e., the second substrate, Si, while the inert gas, e.g., argon, can help to control the ion bombardment.

In some embodiments, Radiofrequency or microwave power is applied to create a plasma within the chamber. In such embodiments, power excites the gas molecules, causing them to ionize and form a plasma of reactive ions and electrons. The plasma can include reactive ions that chemically react with the silicon. The reactive ions bombard the substrate surface, break chemical bonds and remove silicon. The RIE process can be selective, meaning it can mainly affect the target material, i.e., silicon, while leaving other materials, such as masking layers or underlying layers, relatively unaffected.

In some embodiments, to achieve selective etching, an etch mask can be applied on the substrate surface prior to the RIE process. The etch mask protects certain regions from etching, allowing the reactive ions to remove the exposed material selectively. The etching process can be controlled to achieve specific etch profiles, such as vertical sidewalls or tapered structures. Parameters such as gas composition, pressure, power, and process duration are adjusted to achieve the desired etch characteristics. In some embodiments, endpoint detection techniques, such as optical emission spectroscopy or laser interferometry, can be used to determine when the etching process has reached a desired endpoint. This ensures accurate control of the etch depth and prevents over-etching. After the etching process is completed, the substrate can be cleaned to remove any residue or by-products from the etching. Cleaning can involve rinsing with solvents or plasma cleaning to ensure the substrate's surface is free from contaminants.

As a result, portions of sac TiN 244 are removed from the top NS 230. It should be noted that, portions of sac TiN 244 formed around the bottom nanosheets, bottom NS, 232 remain intact. In some embodiments, an OPL reflow process is performed at about 300-350 0C to cover exposed portions of the sac TiN 244 on sidewalls of the isolation box 234.

FIG. 3C illustrates an augmented top view of a nanosheet 306 of the top transistor, in accordance with some embodiments. As depicted, the nanosheet includes the Si 252 in the middle of the nanosheet surrounded by the IL 260. The first gate dielectric 240 is formed over the IL 260. The sac TiN 244 over the first gate dielectric 240 is removed.

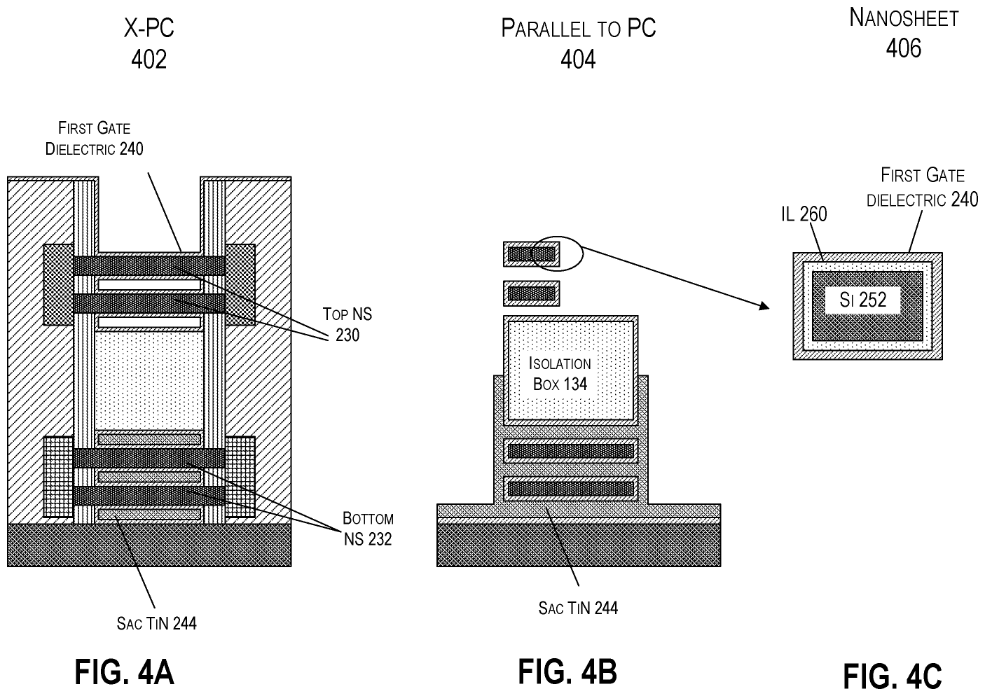

FIGS. 4A-4B illustrate a semiconductor device after OPL removal, in accordance with some embodiments. The semiconductor device is shown across gates 402 and parallel to gates 404. In some embodiments, the OPL is removed. The removal of the OPL can be performed via an ashing process.

FIG. 4C illustrates an augmented top view of a nanosheet 406 of the top transistor, in accordance with some embodiments. As depicted, the nanosheet includes the Si 252 in the middle of the nanosheet surrounded by the IL 260. The first gate dielectric 240 is formed over the IL 260.

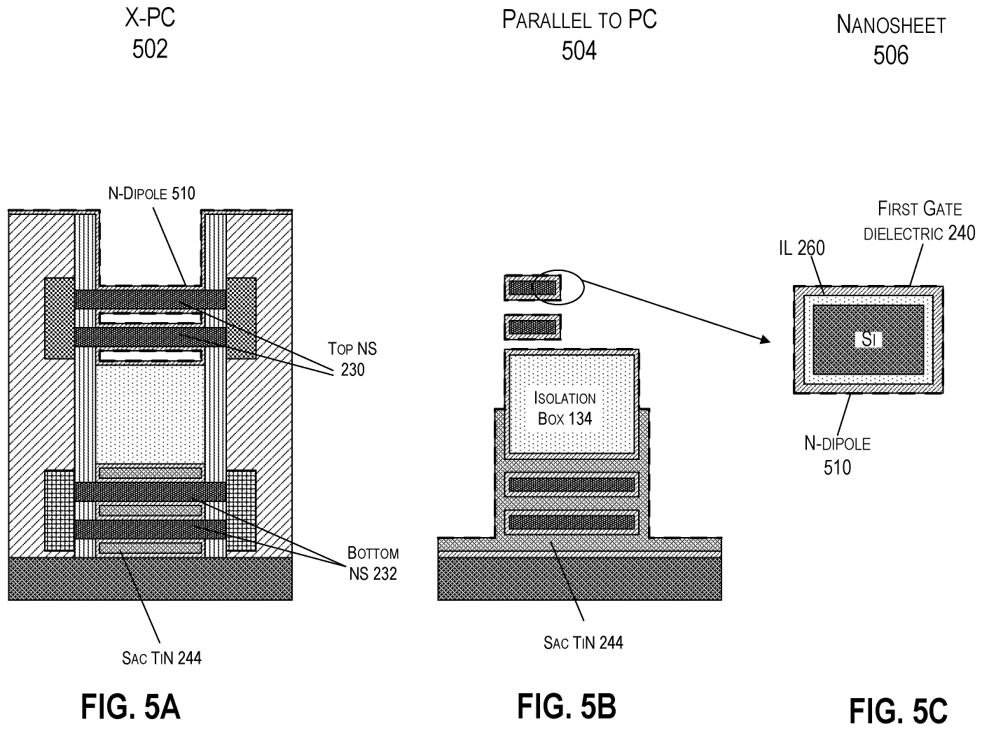

FIGS. 5A-5B illustrate a semiconductor device after the formation of an n-dipole, in accordance with some embodiments. The semiconductor device is shown across gates 502 and parallel to gates 504. In some embodiments, an n-dipole 510 is formed over the top surface of the semiconductor device. The n-dipole 510 can further form on a top surface and a bottom surface of the top NS 230.

In some embodiments, the n-dipole 510 is a thin metallic compound integrated in the transistor gate stack that can shift the work function lower to reduce the threshold voltage for electron conduction in n-channel field effect transistors. The n-dipole 510 can include materials such as lanthanum, aluminum oxides, or fluorine-doped alloys that exhibit natural electron affinity drawing electrons across the underlying gate dielectric. By tuning the effective work function more closely to the intrinsic Fermi level of electron-conducting semiconductor channels, the gate electrode can induce electron inversion at low applied biases. This allows n-type transistors to switch on and pass high drain currents at lower gate voltages. The n-dipole 510 thickness and material composition-whether lanthanum-based, fluorine-rich, or based on other electron-attracting alloys, can directly impact the effectiveness of work function reduction resulting in millivolt-scale threshold optimization. The voltage tuning through n-dipole 510 deposited above the first gate dielectric 240 can facilitate low power consumption.

FIG. 5C illustrates an augmented top view of a nanosheet 506 of the top transistor, in accordance with some embodiments. As depicted, the nanosheet includes the Si 252 in the middle of the nanosheet surrounded by the IL 260. The first gate dielectric 240 is formed over the IL 260. The n-dipole 510 covers the first gate dielectric 240.

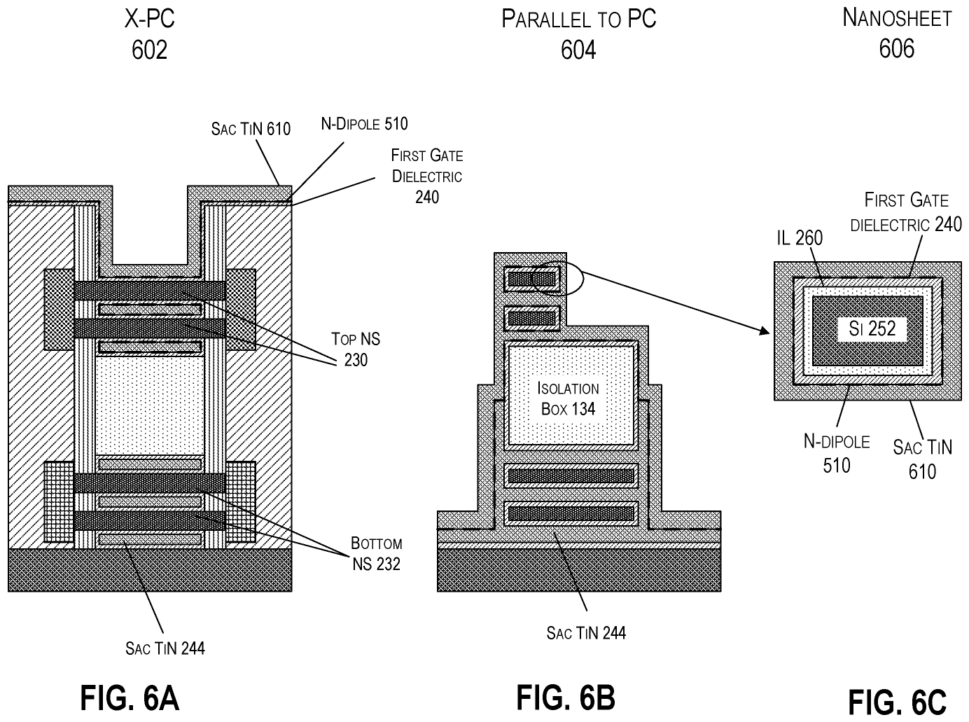

FIGS. 6A-6B illustrate a semiconductor device after the deposition of sacrificial TiN, in accordance with some embodiments. The semiconductor device is shown across gates 602 and parallel to gates 604. In some embodiments, a sacrificial TiN layer, sac TiN, 610 is deposited over the n-dipole 612.

FIG. 6C illustrates an augmented top view of a nanosheet 606 of the top transistor, in accordance with some embodiments. As depicted, the nanosheet includes the Si 252 in the middle of the nanosheet surrounded by the IL 260. The first gate dielectric 240 is formed over the IL 260. The n-dipole 510 covers the first gate dielectric 240 and the sac TIN 610 covers the n-dipole 510.

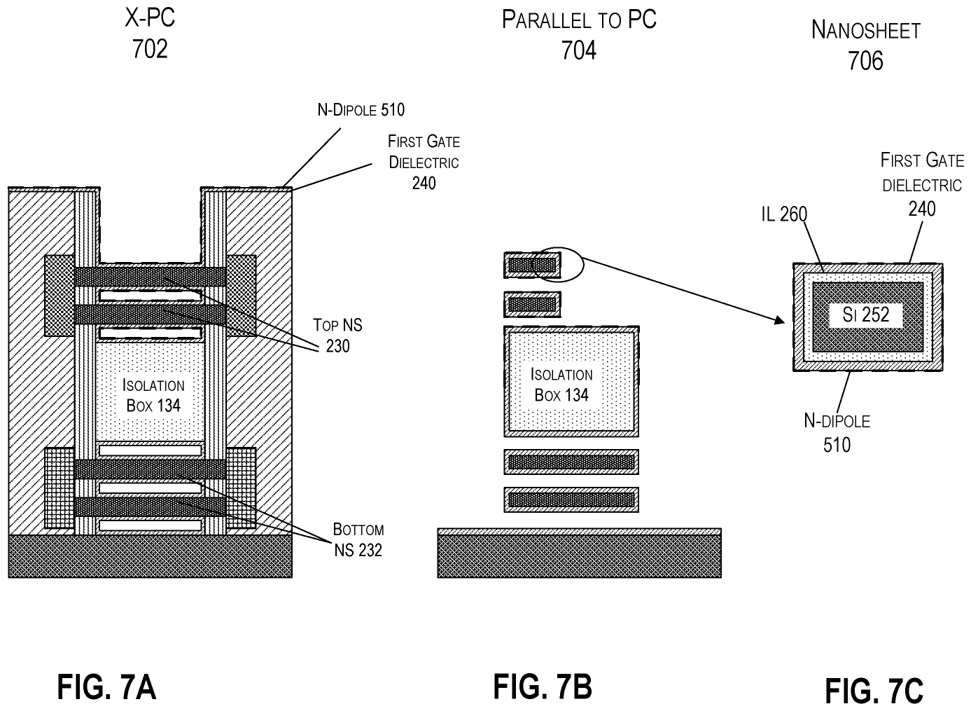

FIGS. 7A-7B illustrate a semiconductor device after the removal of the sacrificial TiN, in accordance with some embodiments. The semiconductor device is shown across gates 702 and parallel to gates 704. In some embodiments, the sacrificial TiN layer, sac TiN, 610 is removed and the n-dipole 510 is exposed. Portions of sac TiN 610 around the NS 232, i.e., sac TiN 244, are further removed from the semiconductor device. As such, the sac TiN including the sac TiN 244 in the bottom transistor and the sac TiN 610 in the top transistor are removed.

FIG. 7C illustrates an augmented top view of a nanosheet 706 of the top transistor, in accordance with some embodiments. As depicted, the nanosheet includes a silicon layer, Si, 252 in the middle of the nanosheet surrounded by the IL 260. The first gate dielectric 240 is formed over the IL 260, and the n-dipole 510 covers the first gate dielectric 240.

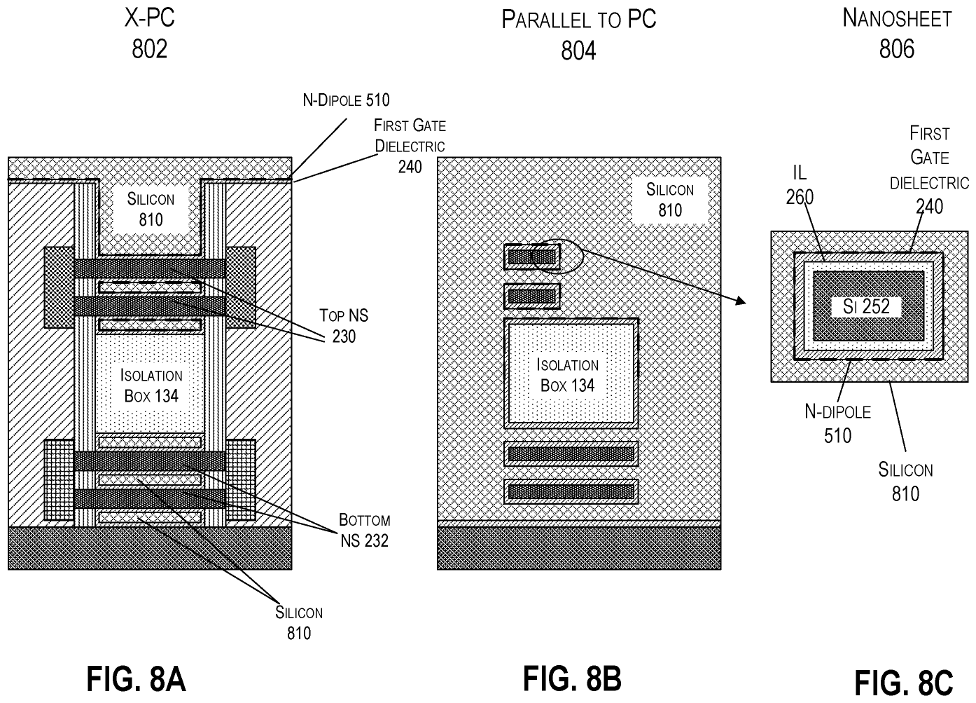

FIGS. 8A-8B illustrate a semiconductor device after the metal gate patterning, in accordance with some embodiments. The semiconductor device is shown across gates 802 and parallel to gates 804. In some embodiments, the metal gate is patterned by forming a layer of silicon, Silicon, 810 over n-dipole 510, which includes the top surface of the semiconductor device and the top surface and the bottom surface of the top NS 230. The Silicon 810 covers the top surface of the top transistor and the top surface and the bottom surface of the bottom NS 232. As shown in FIG. 8B, the Silicon 810 encapsulates the semiconductor device in a parallel to PC view.

FIG. 8C illustrates an augmented top view of a nanosheet 806 of the top transistor, in accordance with some embodiments. As depicted, the nanosheet includes the Si 252 in the middle of the nanosheet surrounded by the IL 260. The first gate dielectric 240 is formed over the IL 260. The n-dipole 510 covers the first gate dielectric 240, and the Silicon 810 covers the n-dipole 510.

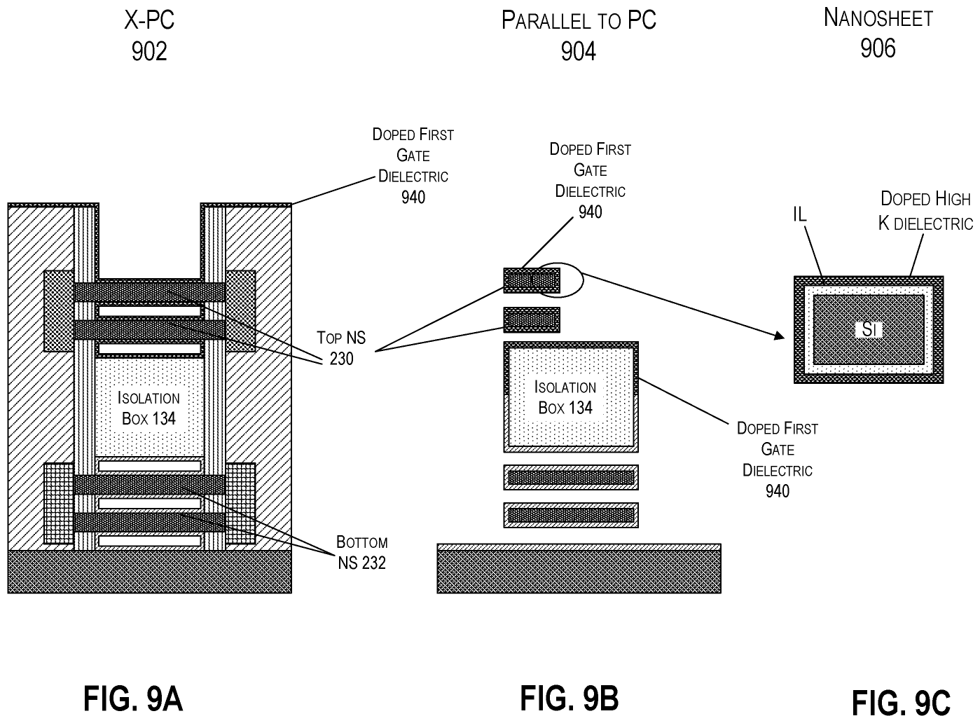

FIGS. 9A-9B illustrate a semiconductor device after the first gate dielectric doping, in accordance with some embodiments. The semiconductor device is shown across gates 902 and parallel to gates 904. In some embodiments, the semiconductor device is annealed and the first gate dielectric is doped with the n-dipole. As a result, the doped first gate dielectric 940 is formed oved the top transistor. As shown in FIG. 9B, portions of the doped first gate dielectric 940 can encapsulate the top NS 230. Portions of the doped first gate dielectric 940 can cover the top surface and the top-half of the sidewalls of the isolation box 134.

FIG. 9C illustrates an augmented top view of a nanosheet 906 of the top transistor, in accordance with some embodiments. As depicted, the nanosheet includes the Si 252 in the middle of the nanosheet surrounded by the IL 260. The doped first gate dielectric 940 is formed over the IL 260.

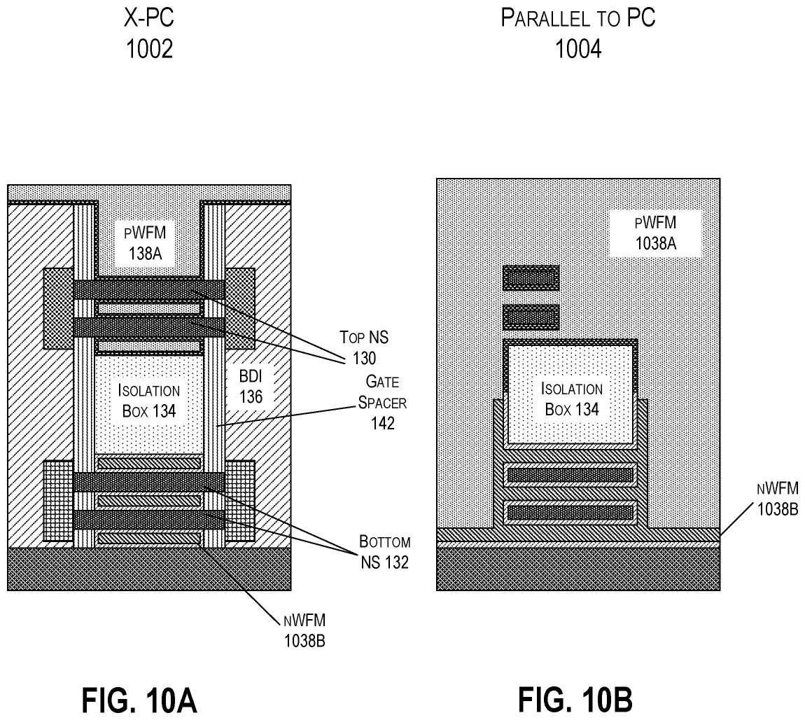

FIGS. 10A-10B illustrate a semiconductor device after the formation of the work function metals, in accordance with some embodiments. The semiconductor device is shown across gates 1002 and parallel to gates 1004. In some embodiments, the top work function metal, nWFM 1038A and the bottom work function metal, pWFM, 1038B are formed. The Work function metallization involves depositing specialized metal alloys as part of integrated circuit fabrication to customize the work function within the transistor gate stacks and tailor device switching thresholds for optimized performance.

In some embodiments, physical vapor deposition (PVD) is utilized to deposit the work function metals. PVD can deposit high-energy magnetically confined argon plasma sputter targeted metals onto the gate dielectric with angstrom-level thickness control to tune work function. The deposition process conditions including ambient argon pressure, wafer temperature and deposition rate can be tuned to control interface quality and morphology. The tuning allows discrete work functions for both n-channel and p-channel devices to be dialed-in through selective deposition, facilitating low-power high-speed complementary circuit operation.

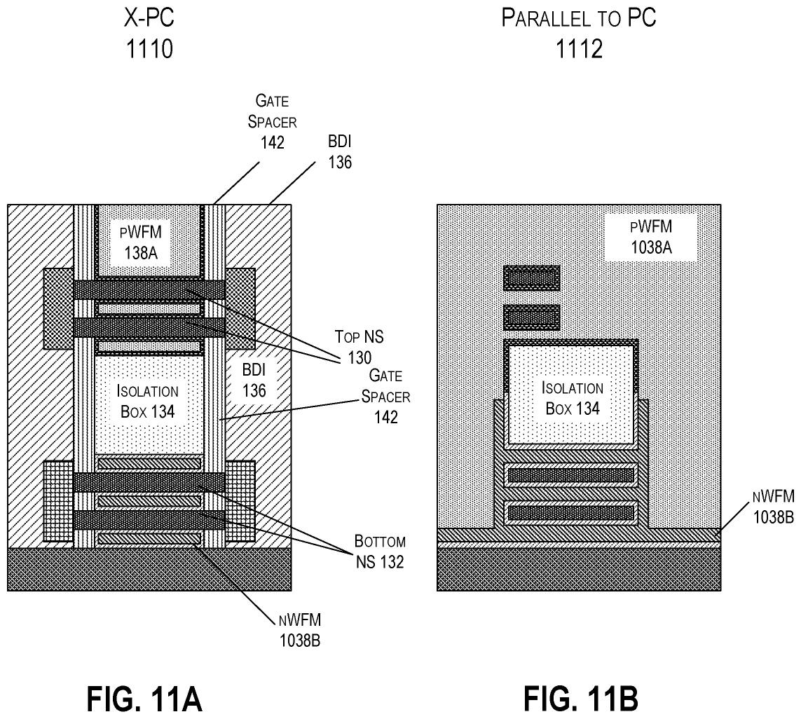

FIGS. 11A-11B illustrate a semiconductor device after removing portions of the top work function metal, in accordance with some embodiments. The semiconductor device is shown across gates 1102 and parallel to gates 1104. In some embodiments, portions of the nWFM 1038A are removed from the top of the semiconductor device. Additionally, portions of the doped first gate dielectric are removed from the top surface of the IL 260. As such, the BDI 136 and the gate spacer 142 are exposed.

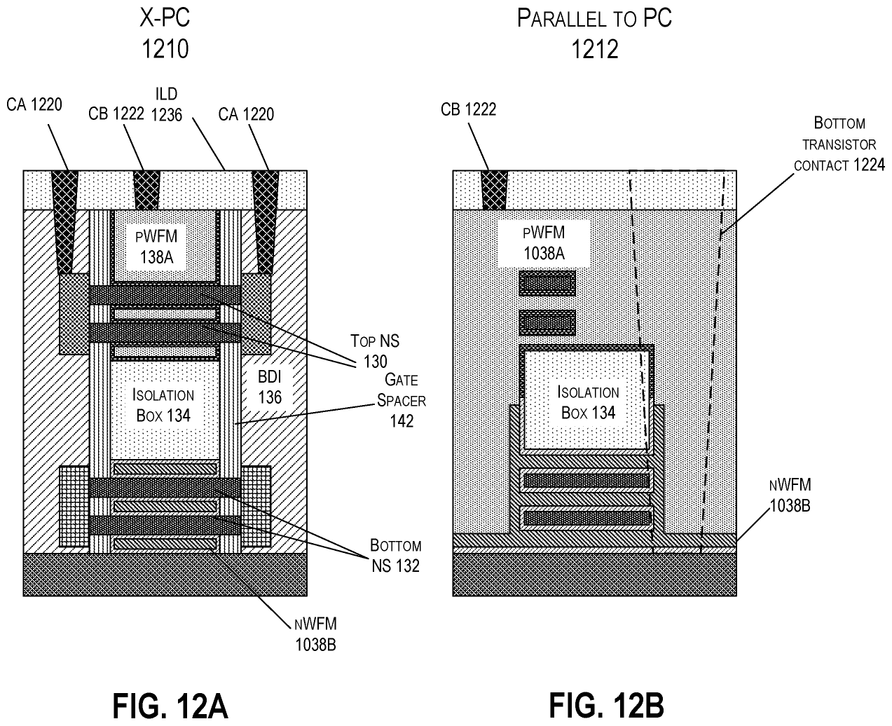

FIGS. 12A-12B illustrate a semiconductor device after the contact formation, in accordance with some embodiments. The semiconductor device is shown across gates 1202 and parallel to gates 1204. In some embodiments, the top source/drain contacts, CA 1220, the top gate contact, CB 1222, and the bottom transistor contact 1224 are formed. Subsequently, an ILD layer, ILD 1236, is formed over the semiconductor device.

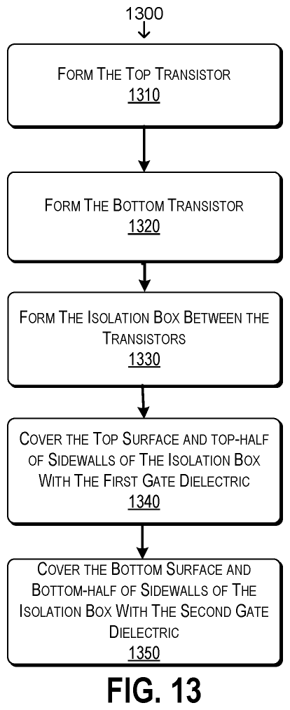

FIG. 13 illustrates a block diagram of a method 1300 for forming the semiconductor device, in accordance with some embodiments. As shown by block 1310, the top transistor is formed.

As shown by block 1320, the bottom transistor is formed.

As shown by block 1330, the isolation box is formed. The isolation box can be formed between the top transistor and the bottom transistor.

As shown by block 1340, a top surface and top-half of sidewalls of the isolation box are covered by a first gate dielectric.

As shown by block 1350, a bottom surface and bottom-half of sidewalls of the isolation box is covered by a second gate dielectric.

In one aspect, the method and structures described above may be used in the fabrication of integrated circuit chips. The resulting integrated circuit chips can be distributed by the fabricator in raw wafer form (that is, as a single wafer that has multiple unpackaged chips), as a bare die, or in a packaged form. In the latter case, the chip may be mounted in a single chip package (such as a plastic carrier, with leads that are affixed to a motherboard or other higher-level carrier) or in a multichip package (such as a ceramic carrier that has either or both surface interconnections or buried interconnections). In any case, the chip can then be integrated with other chips, discrete circuit elements, and/or other signal processing devices as part of either (a) an intermediate product, such as a motherboard, or (b) an end product. The end product can be any product that includes integrated circuit chips, ranging from low-end applications, such as toys, to advanced computer products having a display, a keyboard or other input device, and a central processor.

### CONCLUSION

The descriptions of the various embodiments of the present teachings have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

While the foregoing has described what are considered to be the best state and/or other examples, it is understood that various modifications may be made therein and that the subject matter disclosed herein may be implemented in various forms and examples, and that the teachings may be applied in numerous applications, only some of which have been described herein. It is intended by the following claims to claim any and all applications, modifications, and variations that fall within the true scope of the present teachings.

The components, steps, features, objects, benefits, and advantages that have been discussed herein are merely illustrative. None of them, nor the discussions relating to them, are intended to limit the scope of protection. While various advantages have been discussed herein, it will be understood that not all embodiments necessarily include all advantages. Unless otherwise stated, all measurements, values, ratings, positions, magnitudes, sizes, and other specifications that are set forth in this specification, including in the claims that follow, are approximate, not exact. They are intended to have a reasonable range that is consistent with the functions to which they relate and with what is customary in the art to which they pertain.

Numerous other embodiments are also contemplated. These include embodiments that have fewer, additional, and/or different components, steps, features, objects, benefits and advantages. These also include embodiments in which the components and/or steps are arranged and/or ordered differently.

While the foregoing has been described in conjunction with exemplary embodiments, it is understood that the term “exemplary” is merely meant as an example, rather than the best or optimal. Except as stated immediately above, nothing that has been stated or illustrated is intended or should be interpreted to cause a dedication of any component, step, feature, object, benefit, advantage, or equivalent to the public, regardless of whether it is or is not recited in the claims.

It will be understood that the terms and expressions used herein have the ordinary meaning as is accorded to such terms and expressions with respect to their corresponding respective areas of inquiry and study except where specific meanings have otherwise been set forth herein. Relational terms such as first and second and the like may be used solely to distinguish one entity or action from another without necessarily requiring or implying any actual relationship or order between such entities or actions. The terms “comprises,” “comprising,” or any other variation thereof, are intended to cover a non-exclusive inclusion, such that a process, method, article, or apparatus that comprises a list of elements does not include only those elements but may include other elements not expressly listed or inherent to such process, method, article, or apparatus. An element proceeded by “a” or “an” does not, without further constraints, preclude the existence of additional identical elements in the process, method, article, or apparatus that comprises the element.

The Abstract of the Disclosure is provided to allow the reader to quickly ascertain the nature of the technical disclosure. It is submitted with the understanding that it will not be used to interpret or limit the scope or meaning of the claims. In addition, in the foregoing Detailed Description, it can be seen that various features are grouped together in various embodiments for the purpose of streamlining the disclosure. This method of disclosure is not to be interpreted as reflecting an intention that the claimed embodiments have more features than are expressly recited in each claim. Rather, as the following claims reflect, the inventive subject matter lies in less than all features of a single disclosed embodiment. Thus, the following claims are hereby incorporated into the Detailed Description, with each claim standing on its own as a separately claimed subject matter.

What is claimed is:

1. A semiconductor device, comprising:
a top transistor;
a bottom transistor;
an isolation box between the top transistor and the bottom transistor;
a first gate dielectric, wherein first portions of the first gate dielectric cover a top surface and top-half of sidewalls of the isolation box; and
a second gate dielectric, wherein first portions of the second gate dielectric cover a bottom surface and bottom-half of the sidewalls of the isolation box.

2. The semiconductor device of claim 1, wherein:
the top transistor is stacked over the bottom transistor; and
the top transistor and the bottom transistor are nanosheet field-effect transistors (FETs).

3. The semiconductor device of claim 1, wherein:
second portions of the first gate dielectric encapsulate a first plurality of nanosheets in the top transistor; and
second portions of the second gate dielectric encapsulate a second plurality of nanosheets in the bottom transistor.

4. The semiconductor device of claim 1, wherein the first portions of the first gate dielectric and the first portions of the second gate dielectric form a continuous layer encapsulating the isolation box.

5. The semiconductor device of claim 1, wherein:
the first gate dielectric is made of a first high-k dielectric material; and
the second gate dielectric is made of a second high-k dielectric material.

6. The semiconductor device of claim 5, wherein the first high-k dielectric material and the second high-k dielectric material are a same material.

7. The semiconductor device of claim 5, wherein the first high-k dielectric material and the second high-k dielectric material are different materials.

8. The semiconductor device of claim 1, wherein:
the first gate dielectric is doped with a metal; and
the second gate dielectric is an undoped material.

9. The semiconductor device of claim 1, further comprising:
an n-type work function metal (nWFM) in the bottom transistor; and
a p-type work function metal (pWFM) in the top transistor.

10. The semiconductor device of claim 9, wherein the nWFM includes Al or Ti.

11. A method of fabricating a semiconductor comprising:
forming a top transistor;
forming a bottom transistor;
forming an isolation box between the top transistor and the bottom transistor;
covering a top surface and top-half of sidewalls of the isolation box by a first gate dielectric; and
covering a bottom surface and bottom-half of sidewalls of the isolation box by a second gate dielectric.

12. The method of claim 11, further comprising; stacking the top transistor over the bottom transistor, wherein the top transistor and the bottom transistor are nanosheet field-effect transistors (FETs).

13. The method of claim 11, further comprising:
covering a first plurality of nanosheets in the top transistor by the first gate dielectric; and
covering a second plurality of nanosheets in the bottom transistor by the second gate dielectric.

14. The method of claim 11, further comprising encapsulating the isolation box by the first gate dielectric and the second gate dielectric by connecting the first gate dielectric and the second gate dielectric.

15. The method of claim 11, further comprising doping the first gate dielectric with a dopant.

16. The method of claim 15, wherein the dopant is a metal dopant, wherein the metal dopant is Ti, Al, La, Y, or Mg.

17. The method of claim 11, further comprising:
forming an n-type work function metal (nWFM) in the bottom transistor; and
forming a p-type work function metal (pWFM) in the top transistor.

18. A semiconductor device comprising:
a top transistor;
a bottom transistor;
a first gate dielectric, wherein portions of the first gate dielectric encapsulate a first plurality of nanosheets in the top transistor; and
a second gate dielectric, wherein portions of the second gate dielectric encapsulate a second plurality of nanosheets in the bottom transistor.

19. The semiconductor device of claim 18, wherein:
the first gate dielectric is made of a first high-k dielectric material doped with a metal, and
the second gate dielectric is made of a second high-k dielectric material.

20. The semiconductor device of claim 18, further comprising:
an n-type work function metal (nWFM) in the bottom transistor; and
a p-type work function metal (pWFM) in the top transistor.
